(19) United States
(12) Patent Application Publication
(10) Pub. No.: US 2006/0244087 A1
(43) Pub. Date: Nov. 2, 2006

(54) CMOS image sensors and methods of fabricating same

(76) Inventors: Youngsub You, Gyeonggi-do (KR); Junghwan Oh, Gyeonggi-do (KR); Hunhyoung Lim, Gyeonggi-do (KR); Yongwoo Hyung, Gyeonggi-do (KR)

Correspondence Address: MYERS BIGEL SIBLEY & SAJOVEC, PO BOX 37428, RALEIGH, NC, 27627, US

(21) Appl. No.: 11/222,363

(22) Filed: Sep. 8, 2005

(30) Foreign Application Priority Data
May 2, 2005 (KR) 2005-36632

(51) Int. Cl. H01L 31/0232

(52) U.S. Cl. 257/432; 257/E33.073; 257/E33.076

(57) ABSTRACT

A CMOS image sensor includes an image transfer transistor therein. This image transfer transistor includes a semiconductor channel region of first conductivity type and an electrically conductive gate on the semiconductor channel region. A gate insulating region is also provided. The gate insulating region extends between the semiconductor channel region and the electrically conductive gate. The gate insulating region includes a nitridated insulating layer extending to an interface with the electrically conductive gate and a substantially nitrogen-free insulating layer extending to an interface with the semiconductor channel region. The nitridated insulating layer may be a silicon oxynitride (SiON) layer.

### REFERENCE TO PRIORITY APPLICATION

This application claims priority to Korean Patent Application No. 2005-36632, filed May 2, 2005, the disclosure of which is hereby incorporated herein by reference.

### FIELD OF THE INVENTION

The present invention relates to integrated circuit devices and, more particularly, to integrated circuit image sensors and methods of forming integrated circuit image sensors.

### BACKGROUND OF THE INVENTION

CMOS image sensors typically include a two-dimensional array of image sensor cells containing image transfer transistors therein. These image sensor transistors are configured to control transfer of photo-generated electron-hole pairs that are accumulated during an image sensing time interval. As illustrated by FIG. 1, a conventional CMOS image sensor cell 10 includes a photodiode (P/D), an image transfer transistor TX, a reset transistor RX, a select transistor SX and an access transistor AX, connected as illustrated. The gate terminal of the select transistor SX is connected to a floating diffusion region (F/D). This floating diffusion region F/D receives charge carriers from the photodiode P/D upon enablement of the image transfer transistor TX. These charge carriers are generated when photon radiation is received by the photodiode P/D and electron-hole pairs are generated therein. The charge carriers accumulated in the floating diffusion region F/D operate to bias the gate terminal of the select transistor SX. In addition, enablement of the reset transistor RX operates to reset the floating diffusion region F/D by electrically coupling this region to a positive power supply voltage VDD.

Data, which is reflected by a quantity of charge carriers accumulated in the floating diffusion region F/D, may operate to render the select transistor SX conductive to thereby connected the power supply voltage line VDD to a current carrying terminal of the access transistor AX. The access transistor AX, which is rendered conductive upon receipt of an active high voltage on a corresponding row line (ROW), operates to pass the power supply voltage VDD to an output line (OUT) when both the select transistor SX and the access transistor AX are conductive. To provide high image quality, it is often necessary to have a high degree of charge carrier transfer from the photodiode P/D to the floating diffusion region F/D when the image transfer transistor TX is rendered conductive. This high degree of charge carrier transfer is necessary in order to prevent an occurrence of ghost imaging (i.e., image lag). Ghost imaging may occur when charge carriers generated by the photodiode P/D remain within the photodiode P/D after the image transfer transistor is turned off. This residue of charge carriers typically influences a next immediate collection of photons by the photodiode P/D (e.g., during a next frame of a display/image sequence) and may result in the formation of image artifacts that reduce image quality.

### SUMMARY OF THE INVENTION

Embodiments of the invention include an image sensing device having an image transfer transistor therein. This image transfer transistor includes a semiconductor channel region of first conductivity type and an electrically conductive gate on the semiconductor channel region. A gate insulating region is also provided. The gate insulating region extends between the semiconductor channel region and the electrically conductive gate. The gate insulating region includes a nitridated insulating layer extending to an interface with the electrically conductive gate and a substantially nitrogen-free insulating layer extending to an interface with the semiconductor channel region. This substantially nitrogen-free insulating layer may have a concentration of nitrogen that is less than 10% by weight. In some of these embodiments, the nitridated insulating layer includes silicon oxynitride (SiON), which may be formed by nitridating an upper surface of a silicon dioxide layer. The gate insulating region may have a thickness in a range from about 30 Å to about 100 Å.

Additional image sensing devices according to embodiments of the invention include a semiconductor region having a photodiode therein and an image transfer transistor on the semiconductor region. This image transfer transistor includes a semiconductor channel region of first conductivity type electrically coupled to the photodiode. An electrically conductive gate is provided on the semiconductor channel region. A gate insulating region is also provided that extends between the semiconductor channel region and the electrically conductive gate. The gate insulating region includes a nitridated insulating layer extending to an interface with the electrically conductive gate and a substantially nitrogen-free insulating layer extending to an interface with the semiconductor channel region.

Still further embodiments of the invention include a method of forming an image transfer transistor of an image sensing device. This method includes forming a gate insulating region on a semiconductor substrate and then nitridating an upper surface of the gate insulating region. The nitridating step may include performing a decoupled plasma nitridation (DPN) process on the gate insulating region. This DPN process may be performed at room temperature and may be performed in a reaction chamber receiving about equivalent flow rates of nitrogen gas (N₂) and helium gas (He). An electrically conductive gate is then formed on the nitridated upper surface of the gate insulating region. In some of these embodiments, the nitridating step is followed by the step of annealing the gate insulating region in a nitrogen-containing ambient. The step of forming the electrically conductive gate may also be followed by the step of annealing the gate insulating region in a nitrogen-containing ambient.

In still further embodiments of the invention, the step of forming a gate insulating region includes forming a gate oxide layer on the semiconductor substrate using a radical oxidation process. This radical oxidation process may be performed in a reaction chamber receiving hydrogen (H₂) and oxygen (O₂) gases. The radical oxidation process may also be performed at a temperature in a range from about 450° C. to about 950° C. and at a pressure in a range from about 2 torr to about 5 torr. Moreover, a ratio of flow rates of the oxygen (O₂) and hydrogen (H₂) may be in a range from about 70 to about 110. In particular, the hydrogen (H₂) and oxygen (O₂) gases may be flowed at rates of about 0.1 sccm and about 9.0 sccm, respectively.

### BRIEF DESCRIPTION OF THE DRAWINGS

FIG. 1 is an electrical schematic of a conventional CMOS image sensor cell.

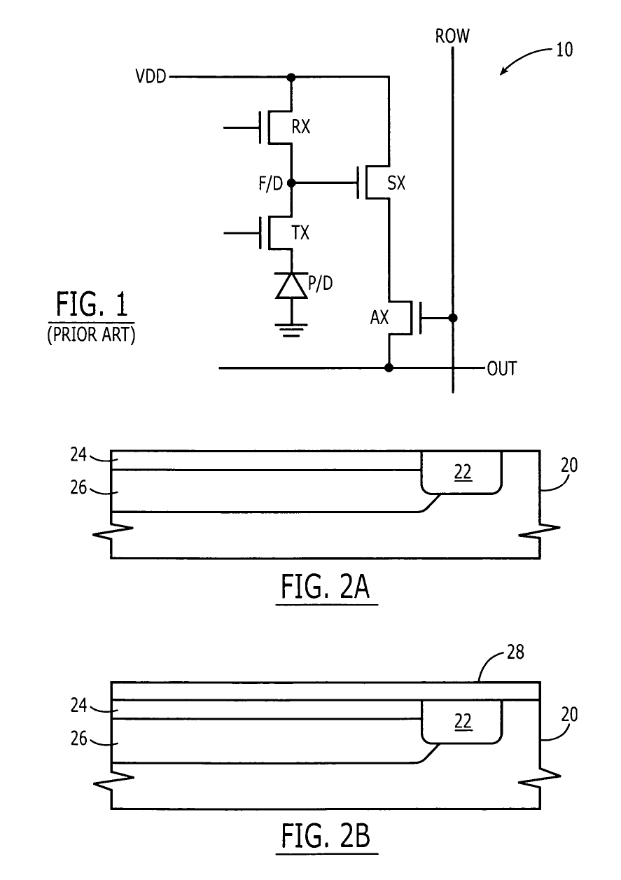

FIGS. 2A-2E are cross-sectional views of intermediate structures that illustrate methods of forming an image transfer transistor according to embodiments of the present invention.

FIG. 3 is a graph that illustrates reaction chamber temperature as a function of time, during a radical oxidation process.

FIG. 4 is a graph that illustrates reaction chamber temperature as a function of time, during a PNA anneal process.

FIGS. 5A-5D are cross-sectional views of intermediate structures that illustrate methods of forming CMOS image sensors according to embodiments of the present invention.

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. Moreover, the terms “first conductivity type” and “second conductivity type” refer to opposite conductivity types such as N or P-type, however, each embodiment described and illustrated herein includes its complementary embodiment as well. Like numbers refer to like elements throughout.

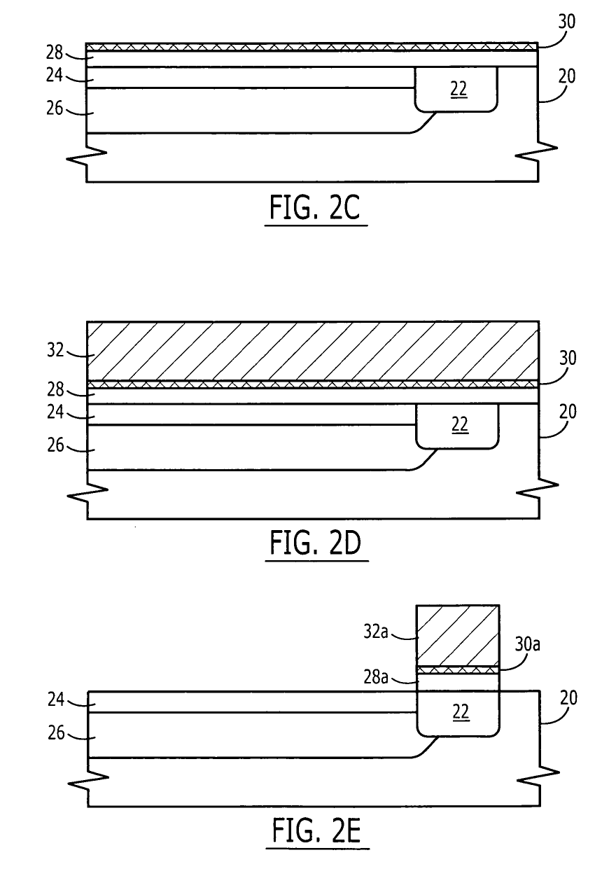

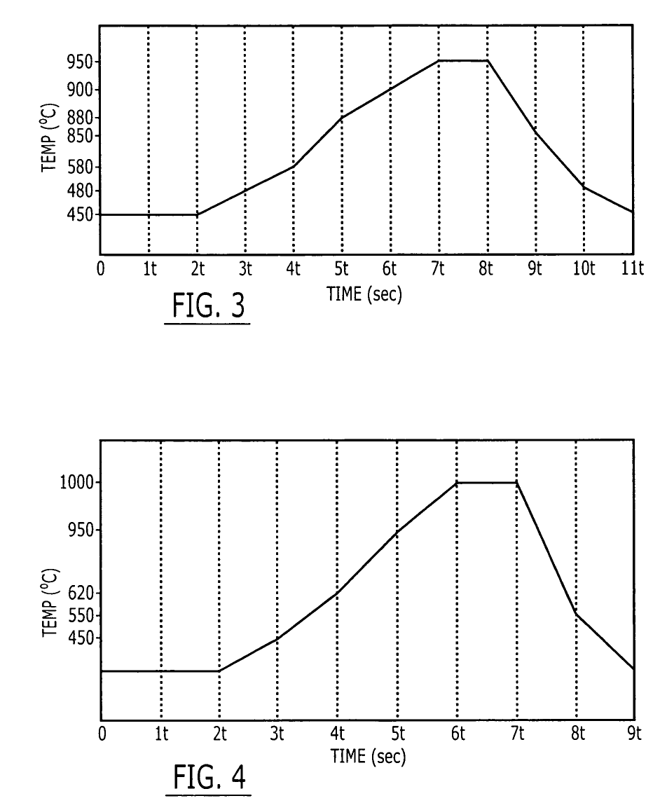

As illustrated by FIG. 2A, methods of forming an image transfer transistor according to embodiments of the present invention include forming a channel region 22 in a semiconductor substrate 20. This channel region 22 may be formed as a P-type region in the event the image transfer transistor is an NMOS transistor or an N-type region in the event the image transfer transistor is a PMOS transistor. The channel region 22 is electrically coupled to a photodiode P/D. This photodiode includes a P-type region 24 (anode) and an N-type region 26 (cathode). The P-type region 24 may be formed by implanting B or BF2 into the substrate 20 and the N-type region 26 may be formed by implanting P or As into the substrate 20. As illustrated by FIG. 2B, a gate insulating layer 28 may be formed on an upper surface of the substrate 20. This gate insulating layer 28 may be formed by a thermal oxidation process, chemical vapor deposition (CVD) or a radical oxidation process. The gate insulating layer 28 may be formed to a thickness in a range between about 30 Å and about 100 Å. A radical oxidation process may be performed in a reaction chamber receiving hydrogen (H₂) and oxygen (O₂) gases and may be performed at a temperature in a range from about 450° C. to about 950° C. As illustrated by FIG. 3, the temperature in the reaction chamber during radical oxidation may vary as a function of time from a lower temperature of 450° C. to a maximum temperature of 950° C., during a time interval from 0 to 11t, where “t” represents a value that may vary in the event the time intervals from 0 to 11t are non-uniform. During the radical oxidation process, the chamber may be maintained at a pressure in a range from about 2 torr to about 5 torr. The hydrogen (H₂) and oxygen (O₂) gases may also be flowed at rates that achieve an oxygen-to-hydrogen rate ratio in a range from about 70 to about 110. In particular, the hydrogen (H₂) and oxygen (O₂) gases may be flowed at rates of about 0.1 sccm and about 9.0 sccm, respectively.

Referring now to FIG. 2C, a thin nitride layer 30 is formed directly on the gate insulating layer 28. This thin nitride layer 30 may be formed within a process chamber using a decoupled plasma nitridation (DPN) process that may convert an upper surface region of silicon dioxide (SiO₂) within the gate insulating layer 28 to silicon oxynitride (SiON). Although not wishing to be bound by any theory, it is believed that this thin nitride layer operates as a dopant barrier (e.g., boron diffusion blocking layer), which blocks out-diffusion of dopants from a subsequently formed gate layer, improves the noise characteristics of the image transfer transistor and inhibits ghost imaging. This DPN process may include flowing N2 and H2 gases at room temperature and at rates equivalent to 100 sccm and 100 sccm, respectively, with a constant chamber pressure of 80 mtorr and a chamber RF power of 500 Watts. This thin nitride layer 30 may be formed to a thickness in a range between about 1 Å and about 10 Å. This DPN process may be performed across a series of time intervals including an initial stabilization time interval (duration=10 sec.), a strike time interval (duration=5 sec.), a nitridation time interval (duration=60 sec.), a dechuck time interval (duration=5 sec.) and a final purge time interval (duration=5 sec.). The stabilization and purge time intervals may be performed at an RF power of 0 Watts and the strike, nitridation and dechuck time intervals may be performed at an RF power of 500 Watts. The DPN process may be followed by an annealing step performed within the process chamber receiving nitrogen and oxygen gases maintained at a pressure of 5 torr.

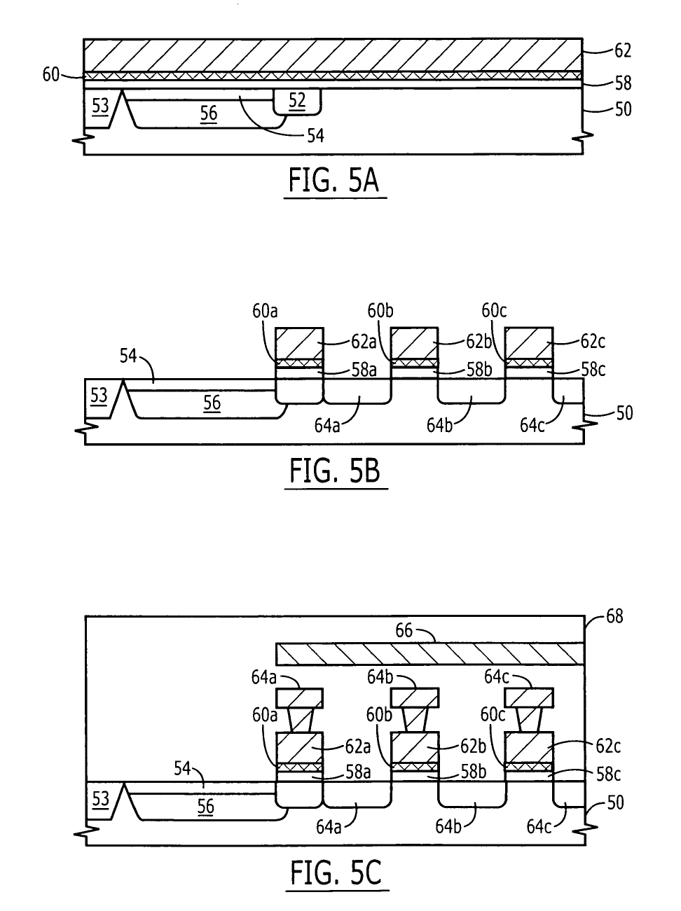

As illustrated by FIG. 4, during a post-nitridation anneal (PNA), the temperature in the reaction chamber may vary as a function of time from a lower temperature of 450° C. to a maximum temperature of 1000° C., during a time interval from 0 to 9t, where “t” represents a value that may vary in the event the time intervals from 0 to 9t are non-uniform. In some embodiments, the PNA step may be performed after a subsequent step of forming an electrically conductive gate layer on the gate insulating layer. An electrically conductive gate layer 32 is formed on the thin nitride layer 30, as illustrated by FIG. 2D. This electrically conductive gate layer 32 may be formed of polycrystalline silicon, for example. Referring now to FIG. 2E, the gate layer 32, nitride layer 30 and gate insulating layer 28 are then photolithographically patterned as regions 32a, 30a and 28a to define an insulated gate electrode of the image transfer transistor.

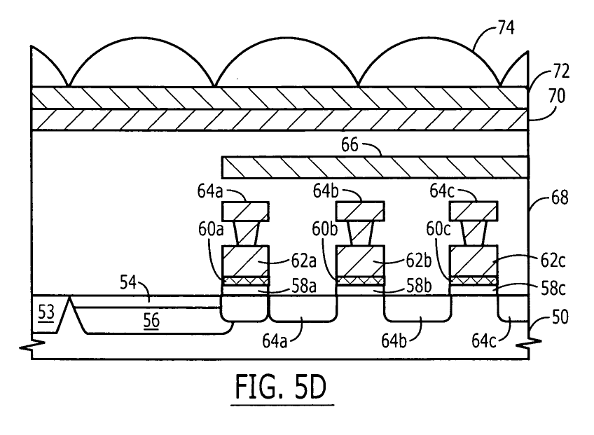

Referring now to FIGS. 5A-5D, methods of forming image sensor devices include forming a trench isolation region 53 and a channel region 52 of first conductivity type in a semiconductor substrate 50. This channel region 52 may be formed as a P-type region in the event the sensor uses NMOS image transfer transistors or an N-type region in the event the sensor uses PMOS image transfer transistors. A photodiode is also formed adjacent the channel region 52. This photodiode is formed as a P-N junction within the substrate 50. This P-N junction includes a P-type region 54 and an N-type region 56. Typical P-type dopants include B and BF2 and typical N-type dopants include As and P. A gate insulating layer 58 is formed on a surface of the substrate 50. This gate insulating layer 58 may be formed using a thermal oxidation process, a chemical vapor deposition (CVD) process or a radical oxidation process, as described above with respect to FIGS. 2A-2E. The gate insulating layer 58 may be formed to a thickness in a range between about 30 Å and about 100 Å. Thereafter, a thin nitride layer 60 is formed directly on the gate insulating layer 58. This thin nitride layer 60 may be formed within a process chamber using a decoupled plasma nitridation (DPN) process that may convert silicon dioxide (SiO₂) within the gate insulating layer 58 to silicon oxynitride (SiON).

This DPN process may include flowing N2 and H2 gases at room temperature and at rates equivalent to 100 sccm and 100 sccm, respectively, with a constant chamber pressure of 80 mtorr and a chamber RF power of 500 Watts. This thin nitride layer 60 may be formed to a thickness in a range between about 1 Å and about 10 Å. This DPN process may be performed across a series of time intervals including an initial stabilization time interval (duration=10 sec.), a strike time interval (duration=5 sec.), a nitridation time interval (duration=60 sec.), a dechuck time interval (duration=5 sec.) and a final purge time interval (duration=5 sec.). The stabilization and purge time intervals may be performed at an RF power of 0 Watts and the strike, nitridation and dechuck time intervals may be performed at an RF power of 500 Watts. The DPN process may be followed by an annealing step performed within the process chamber receiving nitrogen and oxygen gases maintained at a pressure of 5 torr. As illustrated by FIG. 4, during a post-nitridation anneal (PNA), the temperature in the reaction chamber may vary as a function of time from a lower temperature of 450° C. to a maximum temperature of 1000° C., during a time interval from 0 to 9t, where “t” represents a value that may vary in the event the time intervals from 0 to 9t are non-uniform. An electrically conductive gate layer 62 is then formed on the thin nitride layer 60. This electrically conductive gate layer 62 may be formed of polycrystalline silicon, for example.

Referring now to FIG. 5B, the electrically conductive gate layer 62 and the gate insulating layer 58 are then photolithographically patterned to define a gate electrode of an image transfer transistor TX (regions 62a, 60a and 58a), a gate electrode of a reset transistor RX (regions 62b, 60b and 58b) and a gate electrode of a select transistor SX (regions 62c, 60c and 58c). Thereafter a plurality of metal lines 64a, 64b and 64c are formed on corresponding gate electrodes, as illustrated by FIG. 5C. A metal line 66 may also be formed as a light blocking shield within an interlayer insulating layer 68, which may be formed using a CVD process.

Referring now to FIG. 5D, a color filter 70, over coating layer 72 and micro lens array 74 may be formed on the interlayer insulating layer 68 using conventional techniques. Further passivation (not shown) may also be provided on the micro lens array 74.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. An image transfer transistor of an image sensing device, comprising:
a semiconductor channel region of first conductivity type;
an electrically conductive gate on said semiconductor channel region; and
a gate insulating region extending between said semiconductor channel region and said electrically conductive gate, said gate insulating region comprising a nitridated insulating layer extending to an interface with said electrically conductive gate and a substantially nitrogen-free insulating layer extending to an interface with said semiconductor channel region.

2. The image transfer transistor of claim 1, wherein the nitridated insulating layer comprises silicon oxynitride (SiON).

3. The image transfer transistor of claim 1, wherein said electrically conductive gate comprises a polysilicon region of first conductivity type.

4. The image transfer transistor of claim 2, wherein said gate insulating region has a thickness in a range from about 30 Å to about 100 Å.

5. The image transfer transistor of claim 1, wherein said gate insulating region comprises a silicon dioxide layer having a nitridated upper surface.

6. The image transfer transistor of claim 1, wherein a percentage of nitrogen in the substantially nitrogen-free insulating layer is less than about 10% by weight.

7. An image sensing device, comprising:
a semiconductor region having a photodiode therein; and
an image transfer transistor on said semiconductor region, said image transfer transistor comprising:
a semiconductor channel region of first conductivity type electrically coupled to the photodiode;
an electrically conductive gate on the semiconductor channel region; and
a gate insulating region extending between the semiconductor channel region and the electrically conductive gate, said gate insulating region comprising a nitridated insulating layer extending to an interface with the electrically conductive gate and a substantially nitrogen-free insulating layer extending to an interface with the semiconductor channel region.

8. The device of claim 7, wherein the nitridated insulating layer comprises silicon oxynitride (SiON).

9. The device of claim 7, wherein said electrically conductive gate comprises a polysilicon region of first conductivity type.

10. The device of claim 8, wherein said gate insulating region has a thickness in a range from about 30 Å to about 100 Å.

11. The device of claim 7, wherein said gate insulating region comprises a silicon dioxide layer having a nitridated upper surface.

12. A method of forming an image transfer transistor of an image sensing device, comprising the steps of:
forming a gate insulating region on a semiconductor substrate;
nitridating an upper surface of the gate insulating region; and
forming an electrically conductive gate on the nitridated upper surface of the gate insulating region.

13. The method of claim 12, wherein said nitridating step is followed by the step of annealing the gate insulating region in a nitrogen-containing ambient.

14. The method of claim 12, wherein said step of forming the electrically conductive gate is followed by the step of annealing the gate insulating region in a nitrogen-containing ambient.

15. The method of claim 12, wherein said nitridating step comprises performing a decoupled plasma nitridation (DPN) process on the gate insulating region.

16. The method of claim 15, wherein the DPN process is performed at about room temperature.

17. The method of claim 15, wherein the DPN process is performed in a reaction chamber receiving about equivalent flow rates of nitrogen gas (N₂) and helium gas (He).

18. The method of claim 15, wherein the DPN process comprises powering a nitrogen plasma at about 500 Watts.

19. The method of claim 12, wherein said step of forming a gate insulating region comprises forming a gate oxide layer on the semiconductor substrate using a radical oxidation process.

20. The method of claim 19, wherein the radical oxidation process is performed in a reaction chamber receiving hydrogen (H₂) and oxygen (O₂) gases.

21. The method of claim 20, wherein the radical oxidation process is performed at a temperature in a range from about 450° C. to about 950° C.

22. The method of claim 21, wherein the radical oxidation process is performed at a pressure in a range from about 2 torr to about 5 torr.

23. The method of claim 21, wherein the hydrogen (H₂) and oxygen (O₂) gases are flowed at rates of about 0.1 sccm and about 9.0 sccm, respectively.

24. The method of claim 12, wherein said step of forming a gate insulating region comprises forming a gate oxide layer substantially free of nitrogen on the semiconductor substrate.

25. The method of claim 21, wherein a ratio of flow rates of the oxygen (O₂) and hydrogen (H₂) is in a range from about 70 to about 110.
